(19) United States
(12) Patent Application Publication
(10) Pub. No.: US 2021/0226124 A1
(43) Pub. Date: Jul. 22, 2021

(54) ELECTRODE FOR CORRELATED ELECTRON DEVICE

(71) Applicant: Cerfe Labs, Inc., Austin, TX (US)

(72) Inventors: Ming He, San Jose, CA (US); Xueming Huang, Cupertino, CA (US); Paul Raymond Besser, Sunnyvale, CA (US)

(21) Appl. No.: 16/748,555

(22) Filed: Jan. 21, 2020

(51) Int. Cl. H01L 49/00

(52) U.S. Cl. CPC H01L 49/003

(57) ABSTRACT

Subject matter disclosed herein may relate to fabrication of a correlated electron material (CEM) device. In particular embodiments, layers of a CEM to form a correlated electron switch (CES) device may be disposed between layers of electrode material. Use of a metal nitride as an electrode material for at least one terminal of a CES device may simplify processes to implement a CES device in an integrated circuit device such as in back end of line processing.

### BACKGROUND

### Field

This disclosure relates to devices formed from correlated electron material (CEM), and may relate, more particularly, to approaches for fabricating CEM devices, such as may be used in switches, memory circuits, and so forth, which may exhibit desirable impedance switching characteristics.

### Information

Integrated circuit devices, such as electronic switching devices, for example, may be found in numerous types of electronic devices. For example, memory and/or logic devices may incorporate electronic switches suitable for use in computers, digital cameras, smart phones, computing devices, wearable electronic devices, and so forth. Factors that may relate to electronic switching devices, which may be of interest to a designer in considering whether an electronic switching device is suitable for particular applications, may include physical size, storage density, operating voltages, impedance ranges, switching speed, and/or power consumption, for example. Other factors may include, for example, cost and/or ease of manufacture, scalability, and/or reliability.

### BRIEF DESCRIPTION OF THE DRAWINGS

Claimed subject matter is particularly pointed out and distinctly claimed in the concluding portion of the specification. However, both as to organization and/or method of operation, together with objects, features, and/or advantages thereof, it may best be understood by reference to the following detailed description if read with the accompanying drawings in which:

FIG. 1A is an illustration of an embodiment of a current density versus voltage profile of a device formed from a correlated electron material (CEM);

FIG. 1B is an illustration of an embodiment of a switching device comprising a correlated electron material and a schematic diagram of an equivalent circuit of a correlated electron material switch;

FIG. 2 is a cross-section of a switching device formed from a correlated electron material according to an embodiment;

FIGS. 3A through 3D are cross-sectional diagrams illustrating stages in forming a switching device comprising a correlated electron material from deposited layers of material according to an embodiment;

FIGS. 4A through 4E are cross-sectional diagrams illustrating processes to etch electrode material in the formation of a switching device formed from a correlated electron material according to an embodiment;

FIG. 5 is a schematic diagram of a circuit comprising one or more layers of CEM disposed between a top electrode and a bottom electrode to provide a switching device according to an embodiment; and

FIG. 6 is a flow diagram illustrating a process of fabricating and/or constructing a CEM switching device according to embodiments.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

References throughout this specification to one implementation, an implementation, one embodiment, an embodiment, and/or the like indicates that a particular feature, structure, characteristic, and/or the like described in relation to a particular implementation and/or embodiment is included in at least one implementation and/or embodiment of claimed subject matter. Thus, appearances of such phrases, for example, in various places throughout this specification are not necessarily intended to refer to the same implementation and/or embodiment or to any one particular implementation and/or embodiment. Furthermore, it is to be understood that particular features, structures, characteristics, and/or the like described are capable of being combined in various ways in one or more implementations and/or embodiments and, therefore, are within intended claim scope. In general, of course, as has been the case for the specification of a patent application, these and other issues have a potential to vary in a particular context of usage. In other words, throughout the disclosure, particular context of description and/or usage provides helpful guidance regarding reasonable inferences to be drawn; however, likewise, “in this context” in general without further qualification refers to the context of the present disclosure.

Particular aspects of the present disclosure describe methods and/or processes for preparing and/or fabricating correlated electron materials (CEMs) films to form, for example, a correlated electron switch, such as may be utilized to form a correlated electron random access memory (CeRAM), and/or logic devices, for example. Correlated electron materials, which may be utilized in the construction of CeRAM devices and CEM switches, for example, may also comprise a wide range of other electronic circuit types, such as, for example, memory controllers, memory arrays, filter circuits, data converters, optical instruments, phase locked loop circuits, microwave and millimeter wave transceivers, and so forth, although claimed subject matter is not limited in scope in these respects.

In an implementation of a correlated electron switch in a layer of an integrated circuit device, an electrode material such as a noble metal may be disposed between metal oxide layers forming CEM device and metal layers of such an integrated circuit device. In a process of etching to form correlated electron switch, electrode material formed between metal oxide layers and a bottom metal layer may form as residue on sidewalls of metal oxide layers, potentially shorting such a formed correlated electron switch. In an embodiment, forming a metal nitride electrode material between metal oxide layers and a bottom metal layer (e.g., in lieu of a noble metal as an electrode material) may enable greater flexibility in addressing sidewall residue forming during an etching process to form a correlated electron switch.

In this context, a CEM switch, for example, may exhibit a substantially rapid conductive-state-to-insulative-state transition, which may be enabled, at least in part, by electron correlations, which modify electrical properties of the material, rather than solid-state structural phase changes, such as in response to a change from a crystalline to an amorphous state, for example. Such solid-state structural phase changes, such as from crystalline to amorphous states, for example, may bring about formation of conductive filaments in certain resistive RAM devices. In one aspect, a substantially rapid conductor-to-insulator transition in a CEM device may occur responsive to a quantum mechanical phenomenon that takes place within a bulk of a material making up such an CEM device, in contrast to melting/solidification and/or localized filament formation, for example, in phase change and certain resistive RAM devices. Such quantum mechanical transitions between relatively conductive and relatively insulative states, and/or between a first impedance state and a second, dissimilar impedance state, for example, in a CEM device may be understood in any one of several aspects. As used herein, the terms “relatively conductive state,” “relatively lower impedance state,” and/or “metal state” may be interchangeable, and/or may, at times, be referred to as a “relatively conductive and/or lower-impedance state.” Likewise, the terms “relatively insulative state” and “relatively higher impedance state” may be used interchangeably herein, and/or may, at times, be referred to as a “relatively insulative and/or higher impedance state.” Further, in a relatively insulative and/or higher-impedance state, a CEM may be characterized by a range of impedances, and in a relatively conductive and/or lower-impedance state, a CEM may be characterized by a second range of impedances.

In an aspect, a quantum mechanical transition of a CEM between a relatively insulative and/or higher impedance state and a relatively conductive and/or lower impedance state, wherein the relatively conductive and/or lower impedance state is substantially dissimilar from the insulative and/or higher impedance state, may be understood in terms of a Mott transition. In accordance with a Mott transition, a material may switch between a relatively insulative and/or higher impedance state and a relatively conductive and/or lower impedance state if a Mott transition condition occurs. Mott criteria may be defined by (n_{c})^{1/3} a≈0.26, wherein n_{c} denotes a concentration of electrons, and wherein “a” denotes the Bohr radius. If a threshold charge density is achieved, such that Mott criteria is met, a Mott transition may be believed to occur. Responsive to occurrence of a Mott transition, a state of a CEM device may change between a relatively higher resistance and/or higher capacitance state (e.g., a higher-impedance and/or insulative state) and a relatively lower resistance and/or lower capacitance state (e.g., a lower-impedance and/or conductive state) that is substantially dissimilar from the higher resistance and/or higher capacitance state.

In another aspect, a Mott transition may be controlled by a localization of electrons. If carriers, such as electrons, for example, are localized, a strong coulomb interaction between carriers may split bands of the CEM (e.g., split conductive and valence bands) to bring about a relatively insulative (relatively higher impedance) state. If electrons are no longer localized, a weak coulomb interaction may dominate, which may give rise to a removal of band splitting.

Further, in an embodiment, switching from a relatively insulative and/or higher impedance state to a substantially dissimilar and relatively conductive and/or lower impedance state may enable a change in capacitance in addition to a change in resistance. For example, a CEM device may exhibit a variable resistance together with a property of a variable capacitance. In other words, impedance characteristics of a CEM device may include both resistive and capacitive components. For example, in a metallic state, a CEM device may comprise a relatively low electric field that may approach zero, and thus may exhibit a substantially low capacitance, which may likewise approach zero.

Similarly, in a relatively insulative and/or higher impedance state, which may be brought about by a higher density of bound or correlated electrons, an external electric field may be capable of penetrating a CEM and, therefore, such a CEM may exhibit higher capacitance based, at least in part, on additional charges stored within the CEM. Thus, for example, a transition from a relatively insulative and/or higher impedance state to a substantially dissimilar and relatively conductive and/or lower impedance state in a CEM device may result in changes in both resistance and capacitance, at least in particular embodiments. Such a transition may bring about additional measurable phenomena, and claimed subject matter is not limited in this respect.

In an embodiment, a device formed from a CEM may exhibit switching of impedance states responsive to a Mott-transition occurring in a majority of bulk volume of CEM forming a CEM-based device. In an embodiment, a CEM may form a “bulk switch.” As used herein, the term “bulk switch” refers to at least a substantial volume of a CEM switching a device's impedance state, such as between a low impedance and/or conductive state and a high impedance and/or insulative such as responsive to a Mott-transition. For example, in an embodiment, substantially all bulk CEM of a device may switch between a relatively insulative and/or higher impedance state and a relatively conductive and/or lower impedance state (e.g., a “metal” or “metallic state”) responsive to a Mott transition, or from a relatively conductive and/or lower impedance state to a relatively insulative and/or higher impedance state responsive to a reverse Mott transition.

In implementations, a CEM may comprise one or more “d block” elements or compounds of “d block” elements, which correspond to transition metals and/or transition metal oxides (TMOs). CEM devices may also be implemented utilizing one or more “f block” elements or compounds of “f block” elements. A CEM may comprise one or more rare earth elements, oxides of rare earth elements, oxides comprising one or more rare earth transition metals, perovskites, yttrium, and/or ytterbium, or any other compounds comprising metals from the lanthanide or actinide series of the periodic table of the elements, for example, and claimed subject matter is not limited in scope in this respect. A CEM may additionally comprise a dopant, such as a carbon-containing dopant and/or a nitrogen-containing dopant, wherein an atomic concentration of a resulting ligand (e.g., of carbon or nitrogen) in a CEM may be controlled in part to be a particular predefined atomic concentration (e.g., between about 1.0 parts per million (ppm) to about 20.0%). As referred to herein, the term “atomic concentration” means a ratio of a number of atoms of to a total number of atoms in a material.

In this context, a “ligand” as referred to herein means an ion or molecule attached to a metal atom by coordinate bonding. In the case of a metal oxide or metal chalcogenide, for example, such a ligand may comprise ions of oxygen bonding to a metal ion. In a process to form a CEM (e.g., to enhance switching properties of a metal oxide), a dopant may be applied to a host material (e.g., a metal oxide). In this context, a “dopant” or “doping agent” as referred to herein means an impurity that is introduced into a host material to alter one or more original electrical and/or optical properties of the host material. In one embodiment of a metal oxide host material, oxygen may serve as an “intrinsic ligand.” In a particular implementation of a process to form a bulk material having desired properties (e.g., a CEM), application of a dopant may introduce an “extrinsic ligand” such as carbon, nitrogen and/or CO capable of binding with molecules of the host material to substitute for intrinsic ligands if vacancies occur in molecules of the host material. In this context, an extrinsic ligand, as a ligand supplied by an applied dopant, may comprise a “substitutional ligand” that binds to a vacancy of a metal ion.

As the term is used herein, a “d block” element means an element comprising scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), mercury (Hg), rutherfordium (Rf), dubnium (Db), seaborgium (Sg), bohrium (Bh), hassium (Hs), meitnerium (Mt), darmstadtium (Ds), roentgenium (Rg) or copernicium (Cn), or any combination thereof. A CEM formed from or comprising an “f block” element of the periodic table of elements means a CEM comprising a metal or metal oxide, wherein the metal is from the f block of the periodic table of elements, which may include lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), actinium (Ac), thorium (Th), protactinium (Pa), uranium (U), neptunium (Np), plutonium (Pu), americium (Am), berkelium (Bk), californium (Cf), einsteinium (Es), fermium (Fm), mendelevium (Md), nobelium (No) or lawrencium (Lr), or any combination thereof.

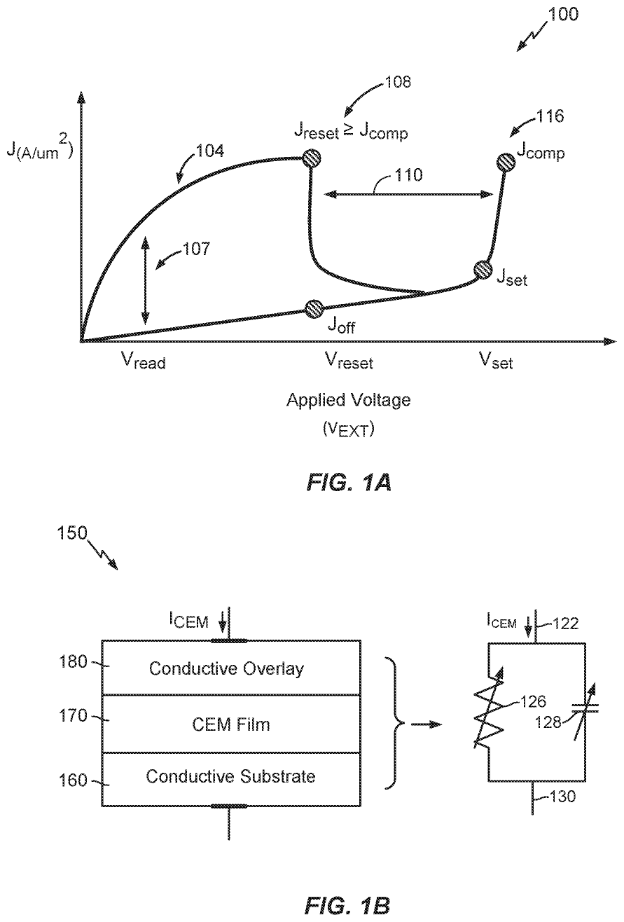

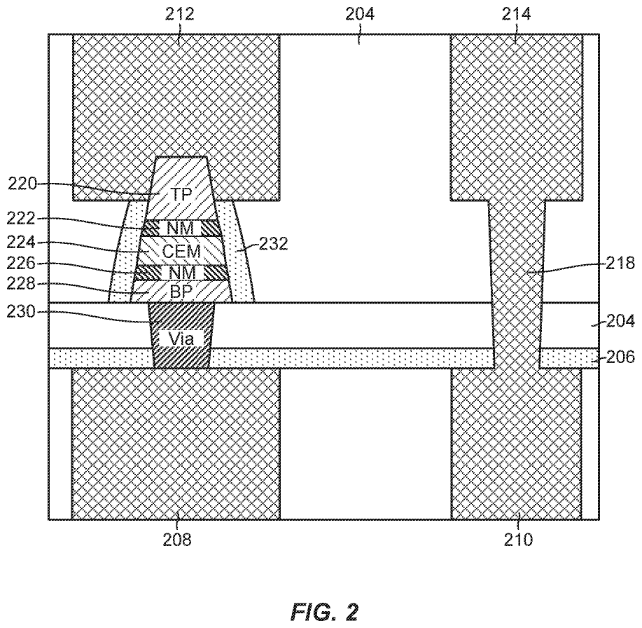

FIG. 1A is an illustration of an embodiment 100 of a current density (J) versus an applied voltage (V_{EXT}) for a device formed from a CEM. At least partially responsive to a voltage applied to terminals of a CEM device, for example, during a “write operation,” such a CEM device may be placed into a relatively low-impedance and/or conductive state or a relatively high-impedance and/or insulative state. For example, application of a voltage Vₛₑt and a current density Jₛₑₜ may enable a transition of a CEM device to a relatively low-impedance and/or conductive state. Conversely, application of a voltage Vᵣₑₛₑₜ and a current density Jᵣₑₛₑₜ may enable a transition of a CEM device to a relatively high-impedance and/or insulative state. As shown in FIG. 1A, reference designator 110 may illustrate a voltage range that may separate Vₛₑₜ from Vᵣₑₛₑₜ. Following placement of a CEM device into a high-impedance state and/or insulative or into a low-impedance and/or conductive state, a particular state of such a CEM device may be detectable by application of a voltage V_{read} (e.g., during a read operation) and detection of a current and/or current density at terminals of the CEM device (e.g., utilizing read window 107).

According to an embodiment, a CEM device characterized in FIG. 1A may comprise any one of several metal oxides, such as, for example, perovskites, Mott insulators, charge exchange insulators, and Anderson disorder insulators, as well as any one of several compounds and/or materials comprising a d block and/or f block element. In one aspect, a CEM device according to FIG. 1A may comprise other types of TMO switching materials, though it should be understood that these are exemplary only and are not intended to limit claimed subject matter. Nickel oxide (NiO) is disclosed as one particular TMO material. NiO materials discussed herein may be doped with substitutional ligands, such as carbon-containing materials (e.g., carbon, carbon monoxide carbonyl (CO)₄), or nitrogen-containing materials, such as ammonia (NH₃), for example, which may establish and/or stabilize material properties and/or enable a p-type operation in which a CEM may be more conductive while placed into a low-impedance and/or conductive state. Thus, in another particular example, NiO doped with substitutional ligands may be expressed as NiO:Lₓ, where Lₓ may indicate a ligand element and/or compound and x may indicate a number of units of the ligand for one unit of NiO. A value of x may be determined for a specific ligand and/or a specific combination of ligands with NiO or with another transition metal compound by balancing valences. Other dopant ligands, which may enable or increase conductivity in a metal oxide in addition to carbonyl may include, for example: nitrosyl (NO), an isocyanide (RNC wherein R is H, C₁-C₆ alkyl or C₆-C₁₀ aryl), a phosphine (R₃P wherein R is C₁-C₆ alkyl or C₆-C₁₀ aryl) for example, triphenylphosphine (PPh₃), an alkyne (e.g., ethyne) or phenanthroline (C₁₂H₈N₂), bipyridine (C₁₀H₈N₂), ethylenediamine (C₂H₄(NH₂)₂), acetonitrile (CH₃CN), fluoride (F), chloride (Cl), bromide (Br), cyanide (CN), sulfur (S), carbon (C), and others.

In this context, a “p-type” doped CEM as referred to herein means a first type of CEM comprising a particular molecular dopant that exhibits increased electrical conductivity, relative to an undoped CEM, while such CEM is operated in a relatively low-impedance and/or conductive state. Introduction of a substitutional ligand, such as CO and/or NH₃ by way of application of a dopant, may operate to enhance a p-type nature of a NiO-based CEM, for example. Accordingly, an attribute of p-type operation of a CEM may include, at least in particular embodiments, an ability to tailor and/or customize electrical conductivity of a CEM at least in part by controlling an atomic concentration of a p-type dopant in a CEM. In particular embodiments, an increased atomic concentration of a p-type ligand may enable increased electrical conductivity of a CEM, although claimed subject matter is not limited in this respect. In particular embodiments, changes in atomic concentration and/or atomic percentage of p-type ligand in a CEM may be observed in characteristics of region 104 of FIG. 1A, as described herein, wherein an increase in p-type ligand may bring about a steeper (e.g., more positive) slope of region 104 to indicate higher conductivity.

In another embodiment, a CEM device represented by a current density versus voltage profile of FIG. 1A, may comprise other TMO materials, such as carbon-containing ligands or nitrogen-containing ligands, though it should be understood that these are exemplary only and are not intended to limit claimed subject matter. NiO, for example, may be doped with substitutional carbon- and/or nitrogen-containing ligands, which may stabilize switching properties in a manner similar to stabilization switching properties responsive to application of a carbon-containing dopant species (e.g., carbonyl). In particular, NiO materials disclosed herein may include nitrogen-containing molecules of the form CₓH_{y}N_{z} (wherein x≥0, y≥0, z≥0, and wherein at least x, y, or z comprise values >0) such as ammonia (NH₃), cyano (CN⁻), azide ion (N₃⁻) ethylene diamine (C₂H₈N₂), phen(1,10-phenanthroline) (C₁₂H₈N₂), 2,2′bipyridine (C₁₀H₈N₂), ethylenediamine ((C₂H₄(NH₂)₂), pyridine (C₅H₅N), acetonitrile (CH₃CN), and cyanosulfanides such as thiocyanate (NCS⁻), for example. NiO switching materials disclosed herein may include members of an oxynitride family (NₓO_{y}, wherein x and y comprise whole numbers, and wherein x≥0 and y≥0 and at least x or y comprise values >0), which may include, for example, nitric oxide (NO), nitrous oxide (N₂O), nitrogen dioxide (NO₂), or precursors with an NO₃— ligand.

In accordance with FIG. 1A, if sufficient bias voltage is applied (e.g., exceeding a band-splitting potential) and an aforementioned Mott condition is satisfied (e.g., injected electron holes are of a population comparable to a population of electrons in a switching region, for example), a CEM device may switch between a relatively low-impedance and/or conductive state and a relatively high-impedance and/or insulative state, for example, responsive to a Mott transition. This may correspond to point 108 of the voltage versus current density profile of FIG. 1A. At, or suitably near this point, electrons may no longer be screened and become localized near a metal ion. This correlation may result in a strong electron-to-electron interaction potential, which may operate to split bands to form a relatively high-impedance and/or insulative material. If a CEM device comprises a relatively high-impedance and/or insulative state, current may be generated by transportation of electron holes. Consequently, if a threshold voltage is applied across terminals of a CEM device, electrons may be injected into a metal-insulator-metal (MIM) diode over a potential barrier of such an MIM device. In certain embodiments, injection of a threshold current of electrons, at a threshold potential applied across terminals of a CEM device, may perform a “set” operation, which may place such a CEM device into a low-impedance and/or conductive state. In a low-impedance and/or conductive state, an increase in electrons may screen incoming electrons and remove a localization of electrons, which may operate to collapse the band-splitting potential, thereby giving rise to a low-impedance and/or conductive state.

In accordance with particular embodiments, current and/or current density in a CEM device may be controlled by an externally applied “compliance” condition, which may be determined at least partially on the basis of an applied external current, which may be limited during a write operation, for example, to place the CEM device into a relatively low-impedance and/or conductive state. This externally applied compliance current may, in some embodiments, also determine a condition of a current density in CEM for a subsequent reset operation to place the CEM device into a relatively high-impedance and/or insulative state. As shown in the particular implementation of FIG. 1A, a voltage Vₛₑₜ may be applied during a write operation to give rise to a current density J_{comp}, such as at point 116, to place the CEM device into a relatively low-impedance and/or conductive state, which may determine a compliance condition for placing the CEM device into a relatively high-impedance and/or insulative state in a subsequent write operation. As shown in FIG. 1A, a CEM device may be subsequently placed into a high-impedance and/or insulative state by application of an externally applied voltage (Vᵣₑₛₑₜ), which may give rise to a current density Jᵣₑₛₑₜ≥J_{comp} at a voltage referenced by 108 in FIG. 1A.

In embodiments, a compliance condition may determine a number of electrons in a CEM device that may be “captured” by holes for a Mott transition. In other words, a current and/or current density applied in a write operation to place a CEM device into a relatively low-impedance and/or conductive memory state may determine a number of holes to be injected to the CEM device for subsequently transitioning the CEM device to a relatively high-impedance and/or insulative state.

As pointed out above, a reset condition may occur responsive to a Mott transition at point 108. As pointed out above, such a Mott transition may give rise to a condition in a CEM device in which a concentration of electrons n approximately equals, or becomes at least comparable to, a concentration of electron holes p. This condition may be modeled according to expression (1) as follows:

$${λ}_{T F} {n}^{\frac{1}{3}} = C \text{\textasciitilde} 0.2 \; 6 \\ n = {( \frac{C}{{λ}_{TF}} )}^{3} \qquad ( 1 )$$

In expression (1), λ_{TF} corresponds to a Thomas Fermi screening length, and C is a constant.

According to an embodiment, a current and/or current density in region 104 of the voltage versus current density profile shown in FIG. 1A may occur responsive to injection of holes from a voltage signal applied across terminals of a CEM device, which may correspond to vp-type operation of the CEM device. Here, injection of holes may meet a Mott transition criterion for a low-impedance and/or conductive state to high-impedance and/or insulative state transition at current I_{MI} as a threshold voltage V_{MI} is applied across terminals of a CEM device. This may be modeled according to expression (2) as follows:

$${I}_{M I} ( {V}_{MI} ) = \frac{dQ ( {V}_{MI} )}{d t} \approx \frac{Q ( {V}_{MI} )}{t} \\ Q ( {V}_{MI} ) = qn ( {V}_{MI} ) \qquad ( 2 )$$

In expression (2), Q(V_{MI}) corresponds to a charged injected (holes or electrons) and may, at least in part, be a function of an applied voltage. Injection of electrons and/or holes to enable a Mott transition may occur between bands and responsive to threshold voltage V_{MI}, and threshold current I_{MI}. By equating electron concentration n with a charge concentration to bring about a Mott transition by holes injected by I_{MI} in expression (2) according to expression (1), a dependency of such a threshold voltage V_{MI} on Thomas Fermi screening length λ_{TF} may be modeled according to expression (3), as follows:

$${I}_{MI} ( {V}_{MI} ) = \frac{Q ( {V}_{MI} )}{t} = \frac{q n ( {V}_{MI} )}{t} = \frac{q}{t} {( \frac{C}{{λ}_{TF}} )}^{3} \\ {J}_{reset} ( {V}_{MI} ) = {J}_{MI} ( {V}_{MI} ) = \frac{{I}_{MI} ( {V}_{MI} )}{{A}_{CEM}} = \frac{q}{{A}_{CEM} t} {( \frac{C}{{λ}_{TF}} )}^{3} \qquad ( 3 )$$

In expression (3), A_{CEM} is a cross-sectional area of a CEM device; and expression (3) may represent a current density through the CEM device to be applied to the CEM device at a threshold voltage V_{MI}, which may place the CEM device into a relatively high-impedance and/or insulative state.

According to an embodiment, a CEM device, which may be utilized to form a CEM switch, a CERAM memory device, and/or a variety of other electronic devices comprising one or more correlated electron materials, may be placed into a relatively low-impedance and/or conductive memory state, such as by transitioning from a relatively high-impedance and/or insulative state, for example, via injection of a sufficient quantity of electrons to satisfy a Mott transition criteria. In transitioning a CEM device to a relatively low-impedance and/or conductive state, if enough electrons are injected and a potential across terminals of such a CEM device overcomes a threshold switching potential (e.g., Vₛₑₜ), injected electrons may begin to screen. As previously mentioned, screening may operate to unlocalize double-occupied electrons to collapse band-splitting potential, thereby bringing about a relatively low-impedance and/or conductive state.

In particular embodiments, changes in impedance states of a CEM device may be brought about by “back-donation” of electrons of compounds comprising NiₓO_{y} (wherein the subscripts “x” and “y” comprise whole numbers). As the term is used herein, “back-donation” refers to a supplying of one or more electrons (e.g., increased electron density) to a metal, metal oxide, or any combination thereof (e.g., to an atomic orbital of a metal), by an adjacent molecule of a lattice structure, such as a ligand and/or dopant. Back-donation also refers to a reversible donation of electrons (e.g., an increase electron density) from a metal atom to an unoccupied π-antibonding orbital on a ligand and/or dopant. Back-donation may permit a metal, metal compound or metal oxide, or a combination thereof, to maintain an ionization state that is favorable to electrical conduction under an influence of an applied voltage. In certain embodiments, back-donation in a CEM, for example, may occur responsive to application of carbon-containing dopants, such as carbonyl (CO)₄, or a nitrogen-containing dopant species, such as ammonia (NH₃), ethylene diamine (C₂H₈N₂), or members of an oxynitride family (NₓO_{y}), for example, which may permit a CEM to exhibit a property in which electrons are controllably, and reversibly, “donated” to a conduction band of a metal or metal oxide, such as nickel or nickel oxide, for example, during operation of a device or circuit comprising a CEM. Back donation may be reversed, for example, in a nickel oxide material (e.g., NiO:CO or NiO:NH₃), thereby permitting such a nickel oxide material to switch to exhibiting a substantially dissimilar impedance property, such as a high-impedance and/or insulative property, during device operation.

Thus, in this context, an electron back-donating material refers to a material that exhibits an impedance switching property, such as switching from a first impedance state to a substantially dissimilar second impedance state (e.g., from a relatively low impedance state to a relatively high impedance state, or vice versa) responsive, at least in part, to an applied voltage to control donation of electrons, and reversal of the electron donation, to and from a conduction band of a CEM.

In some embodiments, by way of back-donation, a CEM switch comprising a transition metal (e.g., in a transition metal compound and/or a transition metal oxide), may exhibit low-impedance and/or conductive properties if such a transition metal, such as nickel, for example, is placed into an oxidation state of 2+ (e.g., Ni²⁺ in a material, such as NiO:CO or NiO:NH₃). Conversely, electron back-donation in a CEM comprising a transition metal, such as nickel, may be reversed by placing such a transition metal into an oxidation state of 1+ or 3+. Accordingly, during operation of a nickel-based CEM device, back-donation may result in “disproportionation,” which may comprise substantially simultaneous oxidation and reduction reactions, substantially in accordance with expression (4), below:

2Ni²+→Ni¹⁺+Ni³⁺ (4)

Such disproportionation, in the specific example of expression (4), refers to formation of nickel ions as Ni¹⁺+Ni³⁺, which may bring about, for example, a relatively high-impedance and/or insulative state during operation of a CEM device. In an embodiment, application of a dopant such as a carbon-containing ligand, carbonyl (CO) and/or a nitrogen-containing ligand, such as an ammonia molecule (NH₃), may permit sharing of electrons during operation of a nickel-based CEM device so as to give rise to the disproportionation reaction of expression (4), and its reversal, substantially in accordance with expression (5), below:

Ni¹⁺+Ni³⁺→2Ni²⁺ (5)

As previously mentioned, reversal of a disproportionation reaction, as shown in expression (5), may permit a nickel-based CEM to return to a relatively low-impedance and/or conductive state.

In embodiments, depending on a molecular concentration of NiO:CO or NiO:NH₃, for example, which may vary from values approximately in the range of an molecular concentration of about 0.1% to about 20.0%, magnitudes of Vᵣₑₛₑₜ and Vₛₑₜ (|Vₛₑₜ| and |Vᵣₑₛₑₜ|, respectively), as shown in FIG. 1A, may vary approximately in the range of about 0.1 V to about 10.0 V subject to the condition that |Vₛₑₜ|≥|Vᵣₑₛₑₜ|. For example, in one possible embodiment, |Vᵣₑₛₑₜ| may occur at a voltage approximately in a range of about 0.1 V to about 1.0 V, and |Vₛₑₜ| may occur at a voltage approximately in a range of about 1.0 V to about 2.0 V, for example. It should be noted, however, that variations in magnitudes of Vₛₑₜ and Vᵣₑₛₑₜ may occur based, at least in part, on a variety of factors, such as atomic concentration of an electron back-donating material, such as NiO:CO or NiO:NH₃ and other materials present in a CEM device, as well as other process variations, and that claimed subject matter is not limited in this respect.

FIG. 1B is an illustration of an embodiment 150 of a switching device comprising a CEM and a schematic diagram of an equivalent circuit of a CEM switch. As previously mentioned, a correlated electron device, such as a CEM switch, a CERAM array, or other type of device utilizing one or more CEMs may comprise a variable or complex impedance device that may exhibit characteristics of both variable resistance and variable capacitance. In other words, impedance characteristics for a CEM variable impedance device, such as a device comprising conductive substrate 160, CEM film 170, and conductive overlay 180, may depend at least in part on resistance and capacitance characteristics of such a device measured across device terminals 122 and 130. In an embodiment, an equivalent circuit for a variable impedance device may comprise a variable resistor, such as variable resistor 126, in parallel with a variable capacitor, such as variable capacitor 128. Of course, although variable resistor 126 and variable capacitor 128 are depicted in FIG. 1B as comprising discrete components, a variable impedance device, such as a device of embodiment 150, may comprise a substantially homogenous CEM film and/or bulk CEM film, and claimed subject matter is not limited in this respect.

Table 1 below depicts characteristics of an example variable impedance device, such as a device of embodiment 150.

TABLE 1
Correlated Electron Switch Truth Table

| Resistance | Capacitance | Impedance |
|---|---|---|
| R_{high}(V_{applied}) | C_{high}(V_{applied}) | Z_{high}(V_{applied}) |
| R_{low}(V_{applied}) | C_{low}(V_{applied} )~0 | Z_{low}(V_{applied}) |

In an embodiment, Table 1 shows that a resistance of a variable impedance device, such as a device of embodiment 150, may transition between a lower resistance state, which, in an example embodiment, may comprise approximately zero (or negligible) resistance state, and a higher resistance that is a function, at least in part, of a voltage applied across such a device. Similarly, Table 1 shows that a capacitance of a variable impedance device, such as a device of embodiment 150, may transition between a lower capacitance state which, in an example embodiment, may comprise approximately zero (or negligible) capacitance, and a higher capacitance state that is a function, at least in part, of a voltage applied across such a device. Accordingly, a device of embodiment 150 may comprise a switching device capable of switching between and a low impedance and/or conductive state and a substantially dissimilar, high-impedance and/or insulative state as a function at least partially dependent on a voltage applied across such a device. In an embodiment, an impedance of a device of embodiment 150 exhibited at a low-impedance and/or conductive state may be approximately in the range of 10⁻¹ to 10⁻⁵ that of an impedance exhibited in a high-impedance and/or insulative state. In other embodiments, an impedance exhibited at a low-impedance and/or conductive state may be approximately in the range of 0.1 to 0.2 that of an impedance exhibited in a high-impedance and/or insulative state, for example. It should be noted, however, that claimed subject matter is not limited to any particular impedance ratios between high-impedance and/or insulative states and low-impedance and/or conductive states.

In certain embodiments, atomic layer deposition may be utilized to form and/or fabricate films comprising NiO materials, such as NiO:CO or NiO:NH₃. In this context, a “layer” as the term is used herein means a sheet and/or coating of material, which may be disposed on and/or over an underlying formation, such as a conductive or insulating substrate. For example, a layer deposited on an underlying substrate by way of an atomic layer deposition process may comprise a thickness dimension comparable to that of a single atom, which may comprise, for example, a fraction of an angstrom (e.g., 0.6 Å). However, in other embodiments, a layer may encompass a sheet and/or coating comprising a thickness dimension greater than that of a single atom depending, for example, on a process utilized to fabricate films comprising one or more CEM films. Additionally, a “layer” may be oriented horizontally (e.g., a “horizontal” layer), oriented vertically (e.g., a “vertical” layer), or may be positioned in any other orientation, such as diagonally, for example. In embodiments, a CEM film may comprise a sufficient number of layers, to permit electron back-donation during operation of a CEM device in a circuit environment, for example, to place such a CEM device in a low-impedance and/or conductive state. Also during operation in a circuit environment, for example, electron back-donation may be reversed so as to give rise to a substantially dissimilar impedance state, such as a high-impedance and/or insulative state, for example.

Also in this context, a “substrate” as used herein means a structure comprising a surface that enables materials, such as materials having particular electrical properties (e.g., conductive properties, insulative properties, etc.) to be deposited, formed and/or placed on and/or over the substrate. For example, in a CEM-based device, a conductive substrate may operate in a manner similar to first conductor 160 to conduct an electrical current to a CEM film in contact with conductive substrate 160. In another example, a substrate may operate to insulate a CEM film to prohibit electrical current flow to and/or from the CEM film. In one possible example of an insulating substrate, a material such as silicon nitride (SiN) may be employed to insulate components of semiconductor structures. Further, an insulating substrate may comprise other silicon-based materials such as silicon-on-insulator (SOI) or silicon-on-sapphire (SOS) technology, doped and/or undoped semiconductors, epitaxial layers of silicon supported by a base semiconductor foundation, conventional metal oxide semiconductors (CMOS), e.g., a CMOS front end with a metal back end, and/or other semiconductor structures and/or technologies, including CES devices, for example. Accordingly, claimed subject matter is intended to embrace a wide variety of conductive and insulating substrates without limitation.

In particular embodiments, formation of CEM films on and/or over a substrate may utilize two or more precursors to deposit components of, for example, NiO:CO or NiO:NH₃, other metal oxide or metal, or combination thereof, onto a conductive material such as a substrate. In an embodiment, layers of a CEM film may be deposited utilizing separate precursor molecules, AX and BY, according to expression (6A), below:

AX_{(gas)}+BY_{(gas)}=AB_{(solid)}+XY_{(gas)} (6A)

In an implementation, “A” of expression (6A) may correspond to a metal, metal compound or metal oxide, or any combination thereof, such as a transition metal, transition metal compound or transition metal oxide, or any combination thereof. In particular embodiments, such a transition metal, transition metal compound and/or transition metal oxide may comprise nickel, but may comprise other metals such as, for example, aluminum, cadmium, chromium, cobalt, copper, gold, iron, manganese, mercury, molybdenum, nickel palladium, rhenium, ruthenium, silver, tantalum, tin, titanium, vanadium, yttrium or zinc (which may be linked to an anion, such as oxygen or other types of ligands), or combinations thereof, although claimed subject matter is not limited in scope in this respect. In particular embodiments, compounds that comprise more than one transition metal oxide may also be utilized, such as yttrium titanate (YTiO₃).

In embodiments, “X” of expression (6A) may comprise a ligand, such as organic ligand, comprising amidinate (AMD), dicyclopentadienyl (Cp)₂, diethylcyclopentadienyl (EtCp)₂, Bis(2,2,6,6-tetramethylheptane-3,5-dionato) ((thd)₂), acetylacetonate (acac), bis(methylcyclopentadienyl) ((CH₃C₅H₄)₂), dimethylglyoximate (dmg)₂, 2-amino-pent-2-en-4-onato (apo)₂, (dmamb)₂ where dmamb=1-dimethylamino-2-methyl-2-butanolate, (dmamp)₂ where dmamp=1-dimethylamino-2-methyl-2-propanolate, Bis(pentamethylcyclopentadienyl) (C₅(CH₃)₅)₂ or carbonyl (CO)₄. Accordingly, in some embodiments, nickel-based precursor AX may comprise, for example, nickel am idinate (Ni(AMD)), nickel dicyclopentadienyl (Ni(Cp)₂), nickel diethylcyclopentadienyl (Ni(EtCp)₂), Bis(2,2,6,6-tetramethylheptane-3,5-dionato)Ni(II) (Ni(thd)₂), nickel acetylacetonate (Ni(acac)₂), bis(methylcyclopentadienyl)nickel (Ni(CH₃C₅H₄)₂, Nickel dimethylglyoximate (Ni(dmg)₂), nickel 2-amino-pent-2-en-4-onato (Ni(apo)₂), Ni(dmamb)₂ where dmamb=1-dimethylamino-2-methyl-2-butanolate, Ni(dmamp)₂ where dmamp=1-dimethylamino-2-methyl-2-propanolate, Bis(pentamethylcyclopentadienyl) nickel (Ni(C₅(CH₃)₅)₂ or nickel carbonyl (Ni(CO)₄), just to name a few examples.

In particular embodiments, layers of a metal oxide film may be formed by application of a dopant operating as an electron back-donating species in addition to precursors AX and BY. An electron back-donating species, which may co-flow with precursor AX, may permit formation of electron back-donating compounds, substantially in accordance with expression (6B), below. In embodiments, a dopant species and/or a precursor to a dopant species, such as carbonyl (CO)₄, ammonia (NH₃), methane (CH₄), carbon monoxide (CO), or other precursors and/or dopant species may be utilized to provide electron back-donating ligands listed above. Thus, expression (6A) may be modified to include an additional dopant ligand comprising an electron back-donating material substantially in accordance with expression (6B), below:

AX_{(gas)}+(NH₃ or other ligand comprising nitrogen)+BY_{(gas)}=AB:NH_{3(solid)}+XY_{(gas)} (6B)

It should be noted that concentrations, such as atomic concentrations, of precursors, such as AX, BY, and NH₃ (or other ligand comprising nitrogen) of expressions (6A) and (6B) may be adjusted to give rise to a resulting atomic concentration of nitrogen-containing and/or carbon-containing dopant to permit electron back-donation in a fabricated CEM device. As referred to herein, the term “ligand atomic concentration” means an atomic concentration of atoms in a finished material that derive from a substitutional ligand (e.g., from application of a dopant). For example, in the case in which a substitutional ligand comprises CO, an atomic concentration of CO in percentage terms comprises a total number of carbon atoms that comprise a material film divided by a total number of atoms in the material film, multiplied by 100.0. In another example, for a case in which a substitutional ligand is NH₃, an atomic concentration of NH₃ comprises a total number of nitrogen atoms in a resulting material film divided by a total number of atoms in the resulting material film, multiplied by 100.0.

In particular embodiments, nitrogen- or carbon-containing dopants may comprise ammonia (NH₃), carbon monoxide (CO), or carbonyl (CO)₄ in an atomic concentration of between about 0.1% and about 20.0%. In particular embodiments, atomic concentrations of dopants, such as NH₃ and CO, may comprise a more limited range of atomic concentrations such as, for example, between about 1.0% and about 20.0%. However, claimed subject matter is not necessarily limited to the above-identified precursors and/or atomic concentrations. It should be noted that claimed subject matter is intended to embrace all such precursors and atomic concentrations of dopants utilized in atomic layer deposition, chemical vapor deposition, plasma chemical vapor deposition, sputter deposition, physical vapor deposition, hot wire chemical vapor deposition, laser enhanced chemical vapor deposition, laser enhanced atomic layer deposition, rapid thermal chemical vapor deposition, spin on deposition, gas cluster ion beam deposition, and/or the like, utilized in fabrication of CEM devices from metal oxide materials. In expressions (6A) and (6B), “BY” may comprise an oxidizer, such as water (H₂O), oxygen (O₂), ozone (O₃), plasma O₂, hydrogen peroxide (H₂O₂). In other embodiments, “BY” may comprise CO, O₂+(CH₄), nitric oxide (NO)+water (H₂O), an oxynitride, or carbon-containing gaseous oxidizing or oxynitridizing agent. In other embodiments, plasma may be used in combination with an oxidizer (BY) to form oxygen radicals (O*). Likewise, plasma may be used in combination with a dopant species to form an activated species to control dopant concentration in a CEM.

In particular embodiments, such as embodiments utilizing atomic layer deposition, a substrate, such as a conductive substrate, may be exposed to precursors, such as AX and BY of expression (6B), as well as dopants providing electron back-donation (such as ammonia or other ligands comprising metal-nitrogen bonds, including, for example, nickel-amides, nickel-imides, nickel-amidinates, or combinations thereof) in a heated chamber, which may attain, for example, a temperature of approximately in the range of 20.0° C. to 1000.0° C., for example, or between temperatures approximately in the range of 20.0° C. and 500.0° C. in certain embodiments. In one particular embodiment, in which atomic layer deposition of NiO:NH₃, for example, is performed, chamber temperature ranges approximately in the range of 20.0° C. and 400.0° C. may be utilized. Following exposure to precursor gases (e.g., AX, BY, NH₃, or other ligand comprising nitrogen), such gases may be purged from the heated chamber for durations approximately in the range of 0.5 seconds to 180.0 seconds, for example. It should be noted, however, that these are merely examples of potentially suitable ranges of chamber temperature and/or time and claimed subject matter is not limited in this respect.

In certain embodiments, a single two-precursor cycle (e.g., AX and BY, as described with reference to expression (6A)) or a single three-precursor cycle (e.g., AX, NH₃, CH₄, or other ligand comprising nitrogen, carbon, or other electron back-donating dopant to provide a substitutional ligand and BY, as described with reference to expression (6B)) utilizing atomic layer deposition may bring about a layer of a metal oxide material film comprising a thickness dimension approximately in the range of 0.6 Å to 5.0 Å per cycle. Accordingly, in one embodiment, if an atomic layer deposition process is capable of depositing layers of a metal oxide material film comprising a thickness dimension of approximately 0.6 Å, 800-900 two-precursor cycles may be utilized to bring about a metal oxide material film comprising a thickness dimension of approximately 500.0 Å. It should be noted that atomic layer deposition may be utilized to form metal oxide material films having other thickness dimensions, such as thickness dimensions approximately in the range of about 15.0 Å to about 1500.0 Å, for example, and claimed subject matter is not limited in this respect.

In particular embodiments, responsive to one or more two-precursor cycles (e.g., AX and BY), or three-precursor cycles (AX, NH₃, CH₄, or other ligand comprising nitrogen, carbon or other back-donating dopant material and BY), of atomic layer deposition, a metal oxide material film may be exposed to elevated temperatures, which may, at least in part, enable formation of a CEM device from a metal oxide material film. Exposure of the metal oxide material film to an elevated temperature may additionally enable activation of a back-donating dopant derived from a substitutional ligand, such as in the form of carbon monoxide, carbonyl, or ammonia, responsive to repositioning of the dopant to metal oxide lattice structures of the CEM device film.

In particular embodiments, a CEM device manufactured in accordance with the above-described process may exhibit a “born on” property in which the device exhibits relatively low impedance (relatively high conductivity) immediately after fabrication of the device. Accordingly, if a CEM device is integrated into a larger electronics environment, for example, at initial activation a relatively small voltage applied to a CEM device may permit a relatively high current flow through the CEM device, as shown by region 104 of FIG. 1A. For example, as previously described herein, in at least one possible embodiment, a magnitude of Vᵣₑₛₑₜ may occur at a voltage approximately in the range of about 0.1 V to about 1.0 V, and a magnitude of Vₛₑₜ may occur at a voltage approximately in the range of about 1.0 V to about 2.0 V, for example. Accordingly, electrical switching voltages operating in a range of about 2.0 V, or less, may permit a memory circuit, for example, to change an impedance state of a CERAM device (e.g., to perform a “write operation” to a CERAM device) or detect an impedance state of a CERAM device (e.g., to perform a “read operation” on a CERAM device), for example. In embodiments, such relatively low voltage operation may reduce complexity, cost, and may provide other advantages over competing memory and/or switching device technologies.

In particular embodiments, two or more CEM devices may be formed within a particular layer of an integrated circuit at least in part by atomic layer deposition, chemical vapor deposition and/or physical vapor deposition of a material to be formed as CEM. In a further embodiment, one or more of a plurality of correlated electron switch devices of a first CEM and one or more of a plurality of correlated electron switch devices of a second CEM may be formed, at least in part, by a blanket deposition. Additionally, in an embodiment, first and second access devices may be positioned substantially adjacent to first and second CEM devices, respectively.

In a further embodiment, one or more of a plurality of CEM devices may be positioned within two or more levels of an integrated circuit at one or more intersections of electrically conductive metal layers of a first level and electrically conductive metal layers of a second level, which may be positioned over the first level of conductive metal layers. In this context a “metal layer” as the term is used herein, means a conductor capable of routing an electrical current from a first location to a second location of a layer of a multi-level CEM switching device. For example, a conductive metal layer may transport electrical current to or from an access device located at an intersection of a conductive metal layer of first level and a conductive metal layer of the second level. In certain embodiments, fabrication of a switching device formed from a multi-level CEM device, such as devices formed utilizing conductive metal layers positioned at multiple levels of a CEM switching device may be utilized in a CEM-based memory devices in which conductive metal layer positioned at multiple levels may facilitate an increase in bit line density, for example. Increases in bit line density may bring about more efficient and/or more highly integrated approaches toward controlling access to memory cells of CEM-based random access memory arrays, for example.

Also in this context, a “level” as the term is used herein, means a discrete surface, which a conductive metal layer may traverse, wherein such a discrete surface may be separated from other discrete surfaces immediately above and/or immediately below, by an insulating material. For example, as described herein, a conductive metal layer traversing a first level may be separated from a conductive metal layer traversing a second level by an insulating material, such as silicon nitride. In this context, a “multi-level” switching device, as the term is used herein, means a device to perform a switching function, such as from a high-impedance and/or insulative state to a low-impedance state, utilizing two or more of the above-described “levels.”

As described herein, in the course of deposition of one or more dopants on or over one or more layers of a first material, such as a transition metal, a transition metal oxide, a transition metal compound and/or transition metal alloy, an amount of an applied dopant may be accurately controlled so as to control an atomic concentration of a resulting ligand in CEM. Additionally, by depositing one or more dopant layers on or over one or more layers of a first material, localized regions of CEM may comprise differing atomic concentrations of dopants so as to provide an approach toward tailoring and/or customizing a dopant concentration profile. Further, dopant concentration profiles within a CEM may be increased via adjusting annealing temperatures and/or annealing durations. In addition to the above-identified advantages, particular embodiments may provide an approach toward fabricating and/or forming three-dimensional structures, such as 3D structures utilized for NAND flash memory. However, claimed subject matter is not limited to the above-identified advantages.

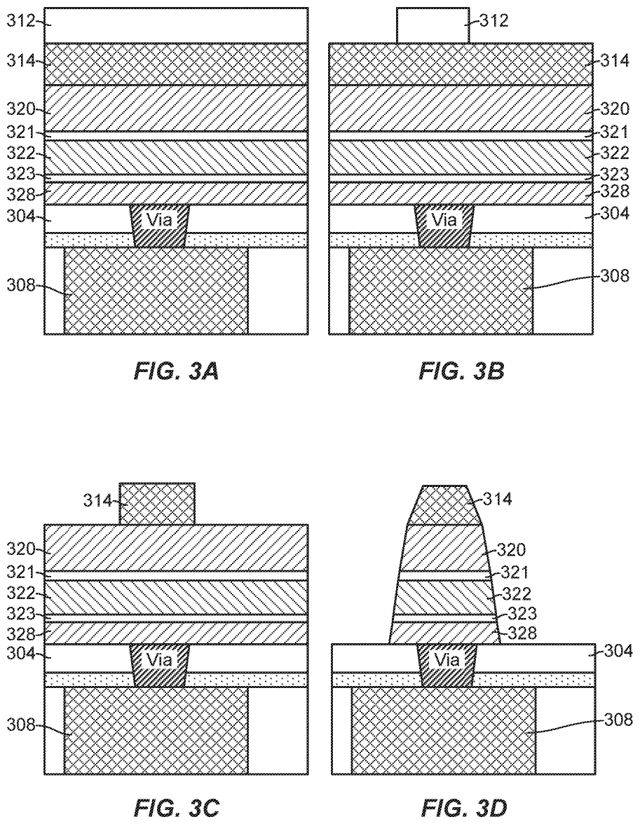

FIG. 2 is a cross-section of a switching device formed from a correlated electron material according to an embodiment. In particular embodiments, processes to form a switching device as shown in FIG. 2 may be performed during back-end-of-line integrated circuit fabrication processes (e.g., to form conducting structures following fabrication of transistor devices and/or other devices in a front-end-of-line integrated circuit fabrication), although in certain embodiments, features of a switching device may be formed during other stages of a circuit fabrication process, and claimed subject matter is not limited in this respect. Here, one or more layers of a correlated electron material (CEM) 224 may be disposed between a top plate layer 220 and a bottom plate layer 228. Bottom plate layer 228 and top plate layer 220 may comprise a conductive material such as TaN. Top plate layer 220 may conduct a signal between metal layer 212 and layers of CEM 224 while bottom plate 228 and metal via 230 may conduct a signal between metal layer 208 and layers of CEM 224. According to an embodiment, layers of CEM 224 may be formed as a correlated electron switch behaving as illustrated in FIG. 1A as described above. In an embodiment, a pulse signal may be applied to top plate layer 220 to affect a voltage and current density in layers of CEM 224 to effect a write operation to change an impedance state of layers of CEM 224 between a low impedance and/or conductive state and a high impedance and/or insulative state. As illustrated in in FIG. 1A. For example, a pulse applied to top layer 220 may bring about a voltage Vₛₑₜ across layers of CEM 224 and a current density Jₛₑₜ in at least a portion of layers of CEM 224 provide to place layers of CEM 224 in a low impedance and/or conductive state. Similarly, a pulse signal applied to top plate layer 220 may bring about a voltage Vᵣₑₛₑₜ across layers of CEM 224 and a current density Jᵣₑₛₑₜ≥J_{comp} in at least a portion of layers of CEM 224 provide to place layers of CEM 224 in a high impedance and/or insulative state.

In the particular illustrated embodiment, a switching device comprising layers of CEM 224, bottom plate layer 228 and top plate layer 220 may be formed on a substrate 204 comprising a dielectric material, which is formed over a capping layer 206. In certain embodiments, substrate 204 may comprise a thickness of between about 1.0 nm and about 50.0 nm, just as an example, and comprise a material such as a fluorosilicate glass having a relatively low relative dielectric constant, such as between about 2.0 and about 4.2, for example. However, in other embodiments, substrate 204 may comprise a material different from fluorosilicate glass, such as, for example, fluorine-doped silicon dioxide, carbon-doped silicon dioxide, spin-on organic polymer dielectric, and so forth.

Substrate 204 may be formed on capping layer 206. Capping layer 206 may operate to reduce or preclude moisture from entering from metal layer 208 and may comprise a material such as silicon nitride, silicon carbon nitride or aluminum nitride, or any combination thereof, and claimed subject matter is not limited to any particular type of capping material. In particular embodiments, capping layer 206 may comprise a thickness of between about 0.5 nm and about 20.0 nm, for example, although claimed subject matter is intended to embrace capping layers comprising a variety of thicknesses, virtually without limitation.

Following formation of capping layer 206 and substrate 204 on or over metal layer 208, via 230 may be formed, such as by way of an etching process followed by a metal filling process. In particular embodiments, such an etching process to form via 230 may comprise a reactive ion etching or sputter etching process, just to name a couple of examples. Following completion of an etching process, via 230 may be formed by filling an etched volume with a suitable material such as tungsten, for example, which may provide an electrically conductive path between metal layer 208 and, for example, bottom plate layer 228. It should be noted, however, that via 230 may comprise a conductive material other than tungsten, and claimed subject matter is not limited in this respect.

Sealing layer 232 may comprise an atomic or molecular concentration of at least 50.0% silicon nitride (SiN), silicon oxynitride (SiON), silicon carbon nitride (SiCN), silicon carbide (SiC) or aluminum nitride (AlN), or any combination thereof, for example. In particular embodiments, sealing layer 232 may comprise a material having a relative dielectric constant of, for example, between about 3.0 and about 10.0, for example. However, in other embodiments, sealing layer 232 may comprise a material having a dielectric constant within the range of about 2.0 to about 20.0, and claimed subject matter is not limited in this respect. Sealing layer 232 may comprise a thickness of, for example, between about 2.0 nm, and about 100.0 nm, although claimed subject matter is intended to embrace any useful thickness of sealing layer 232.

In embodiments, insulative filling material 204 may comprise any suitable dielectric material having a dielectric constant of, for example, between about 2.0 and about 4.5. In certain embodiments, insulative filling material 204 may comprise silicon dioxide (SiO₂) having a dielectric constant of about 3.9. However, claimed subject matter is intended to embrace a variety of insulative filling material materials, such as SiO₂, silicon nitride (SiN), titanium dioxide (TiO₂), and so forth, virtually without limitation.

According to an embodiment, layers of CEM 224 may be formed from a metal oxide such as, for example, NiO and/or other metal oxides such as, for example, HfOx, YOx, TiOx and/or TaOx, just to name a few. Metal oxide making up layers of CEM 224 may also be doped with a carbon-containing dopant such as, for example, CO to a particular atomic concentration. In alternative implementations, metal oxide making up layers of CEM 224 may be doped with other dopants such as NO (e.g., activated with an ambient O₂/N₂ gas mixture) to enable desired switching behavior for a CEM device.

In the presently illustrated embodiment, a layer of electrode material 222 may be disposed between top plate layer 220 and layers of CEM 224, and a layer of electrode material 226 may be disposed between bottom plate layer 228 and layers of CEM 224. In an embodiment, layers of electrode material 222 and 226 may comprise a noble metal such as, for example, silver, gold, platinum, rhodium, iridium, palladium, ruthenium, and/or rhenium. In an implementation, layers of electrode material 222 and 226 formed from a noble metal may inhibit and/or prevent escape of oxygen from layers of CEM 224 into top plate layer 220 and/or bottom plate layer 228. Additionally, a noble metal forming electrode layers 222 and 226 may provide a sufficient work function to enable application of a pulse signal to layers of CEM 224 to affect a change in impedance state such as in a write operation.

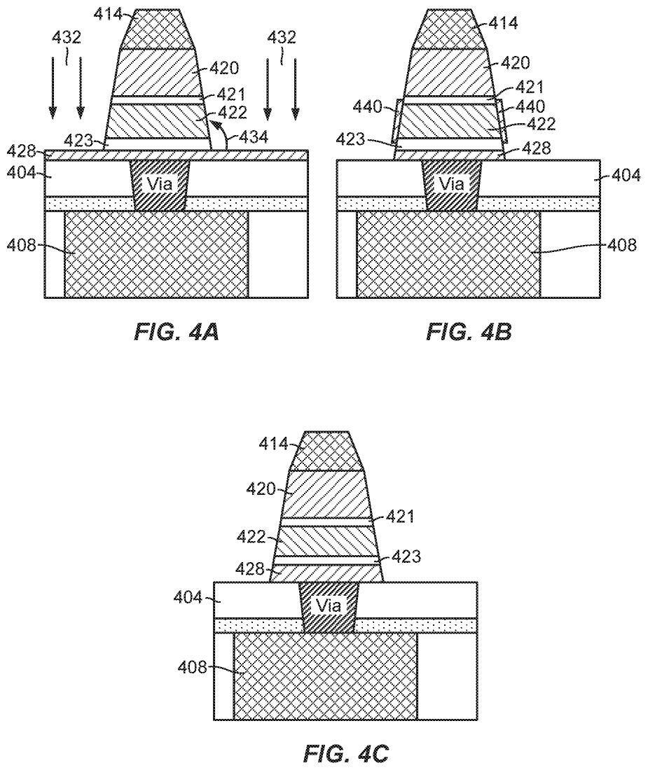

FIGS. 3A through 3D are cross-sectional diagrams illustrating stages in forming a switching device comprising a correlated electron material from deposited layers of material, such as a switching device shown in FIG. 2, according to an embodiment. A lithographic film layer 312 may be disposed over a hard mask layer 314 (e.g., formed from an oxide or TiN). In a transition from FIG. 3A to FIG. 3B, portions of lithographic film layer may be removed according to a pattern to expose portions of hard mask layer 314. Exposed portions of hard mask layer 314 may then be removed as shown in FIG. 3C. According to an embodiment, a dry etch process may be applied to the structure shown in FIG. 3C to by, for example, applying an ion beam etch, plasma sputter etch or other anisotropic etching process, or a combination thereof, which may occur in an etching chamber. Such a dry etch process applied to the structures shown in FIG. 3C may remove portions of top plate layer 320, electrode layer 321, CEM layers 322, electrode layer 323 and bottom plate layer 328 to provide a remaining switch device disposed under hard mask 314. Such a dry etch process may stop at a surface of substrate 304.

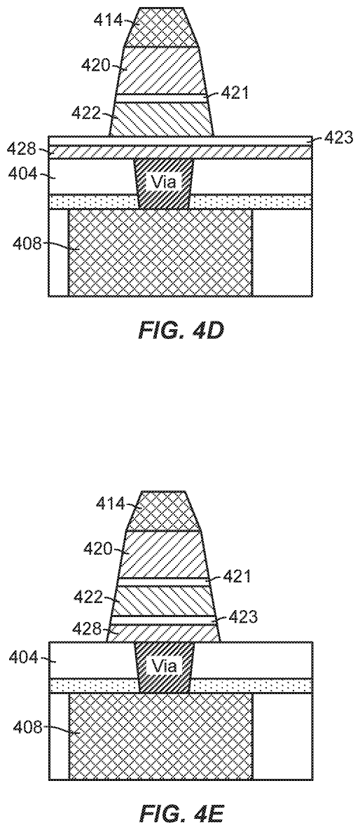

As illustrated in FIGS. 4A and 4B, a process of dry etching to remove portions of electrode layer 323 in FIG. 3D may result in formation of a metallic residue on a sidewall from a resputterring of material forming electrode layer 323. As shown in FIG. 4A, a dry etch process 432 may remove portions of top plate layer 420, electrode layer 421, CEM layers 422, electrode layer 423 and bottom plate layer 428 to provide a remaining switch device disposed under hard mask 414. In applying dry etch process 432 to remove portions of electrode layer 423, at least a part a removed portion of electrode layer 423 may be resputtered as metal particles 434 to collect as sidewall residue 440 as shown in FIG. 4B. Metallic sidewall residue 440 may then at least in part introduce a short circuit across CEM layers 422.

One particular technique for addressing resputtered metals collecting as a sidewall residue is to apply an oxidation treatment following an etching stage. By oxidizing a metallic sidewall residue, the metallic sidewall residue may become inert and/or insulative metal oxide, thereby removing a short caused by the metallic sidewall residue. As pointed out above, electrode layer 423 may comprise a noble metal may be disposed between a bottom plate layer (e.g., bottom plate layer 228) and CEM layers (e.g., CEM layers 224). If, in the course of dry etching, such noble metal electrode material deposits as metallic sidewall residue 440, such deposited noble metal electrode material may not be sufficiently oxidized using an oxidation treatment so as to render the deposited noble metal electrode material inert and/or insulative metal oxide. Additionally, such noble metal electrode material deposits as metallic sidewall residue 440 may not be easily removed (e.g., using a wet clean process).

According to an embodiment, electrode material of electrode layer 423 disposed between CEM layers 422 and bottom plate layer 428 may be replaced with an electrode material comprising metal nitride that may provide a sufficient oxygen barrier between CEM layers 422 and bottom plate layer 428. For example, such a metal nitride may provide an inert layer to inhibit and/or prevent oxygen from escaping a metal oxide forming CEM layers 422. Such a metal nitride material of electrode layer 423 may comprise, for example, one or more of TiN, TaN, MgN, BN or AlN, just to provide a few examples of metal nitrides that may provide a sufficient oxygen barrier. In an embodiment, such an electrode material may be sufficiently rich in nitrogen to be effective in providing an oxygen barrier such as to have an atomic concentration of nitrogen of at least 50% and/or substantially no metal-to-metal bonds.

According to an embodiment, metallic sidewall residue 440 formed from a resputterring of an electrode material comprising a metal nitride may readily oxidized so as to become more insulative by, for example, an in-situ oxidation treatment (e.g., 02 plasma and/or O₂ thermal anneal). Alternatively, application of a reactive ion etch cleaning process with a Cl₂-based chemical may remove resputtered metal residue (e.g., from Ti, Ta, Mg, B or Al). In yet another alternative implementation, application of a wet clean process (e.g., a room temperature SC1 solvent, nitric acid or diluted HCl) may remove sidewall residue (e.g., Ni, Ti, Ta, Mg, B or Al) formed by a resputterring of a metal nitride.

In an alternative to application of an oxidation process or chemical removal process to a metal sidewall residue (e.g., from resputterring of electrode material formed from TiN, TaN, MgN, BN or AlN), electrode material may be etched using an reactive ion etch (RIE) process. For example, as illustrated in FIG. 4D, portions of hard mask layer 414, top plate layer 420, electrode layer 421 and layers of CEM 422 may be removed by application of an ion beam etch (IBE) process which terminates and/or stops after removal of portions of layers of CEM 422 and prior to etch of electrode layer 423 and bottom plate layer 428. Portions of bottom plate 428 and electrode layer 423 (e.g., including a metal nitride electrode material such as TiN, TaN, MgN, BN or AlN) may be removed by application of a reactive ion etch (RIE) process to provide a device as shown in FIG. 4E. Here, such an RIE process applied to a metal nitride electrode material may create a volatile metal biproduct metal that may reduce resputterring of metal to form as sidewall residue. Additionally, any resulting residue from application of an RIE process to a metal nitride electrode material may be addressed by application of an oxidation process or chemical removal process to a metal sidewall residue as described above.

According to an embodiment, layers of material to form a switching device as illustrated in FIGS. 3A through 3D and FIGS. 4A through 4E (e.g., hard mask layers 314 and 414, top plate layers 320 and 420, electrode layers, 321, 323, 421 and 423, layers of CEM 322 and 422, and bottom plate layers 328 and 428) may be formed in a chamber using any one of several suitable deposition processes such as, for example, atomic layer deposition, chemical vapor deposition, plasma chemical vapor deposition, sputter deposition, physical vapor deposition, hot wire chemical vapor deposition, laser enhanced chemical vapor deposition, laser enhanced atomic layer deposition, rapid thermal chemical vapor deposition, spin on deposition, gas cluster ion beam deposition, and/or the like, utilized in fabrication of CEM devices from metal oxide materials. It should be noted, however, that particular layers in devices shown in FIGS. 3A through 3D and 4A through 4D may be formed utilizing other, different processes, and that claimed subject matter is not intended to be limited in this respect.

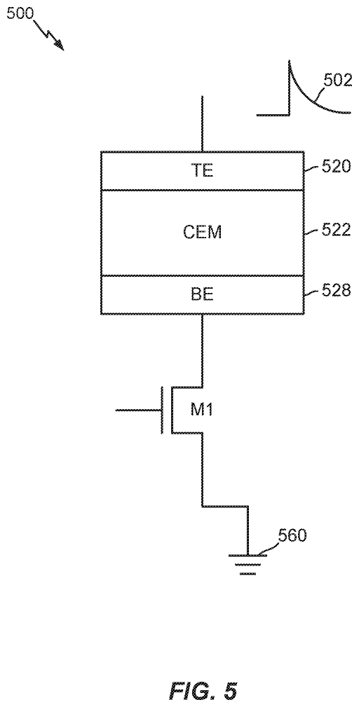

FIG. 5 is a schematic diagram of a circuit comprising one or more layers of CEM 522 disposed between a top electrode (TE) 520 and a bottom electrode (BE) 528 to provide a switching device according to an embodiment. In an implementation, circuit 500 may comprise schematic diagram of an equivalent of switch device shown in FIG. 4C or 4E. To place CEM layers 522 in a particular impedance state, transistor M1 may be closed to couple BE 528 to a reference node 560 while a pulse signal 502 is applied to TE 520. For example, application of pulse signal 502 while transistor M1 is closed may bring about a voltage Vₛₑₜ across CEM layers 522 and a current density Jₛₑₜ in at least a portion of CEM layers 522 to place CEM layers 522 in a low impedance and/or conductive state. Likewise, application of pulse signal 502 while transistor M1 is closed may bring about a voltage Vᵣₑₛₑₜ across CEM layers 522 and a current density Jᵣₑₛₑₜ≥J_{comp} in at least a portion of CEM layers 522 to place CEM layers 522 in a high impedance and/or insulative state.

Pulse signal 502 may comprise a positive polarity relative to BE 528. In the particular implementation illustrated in FIG. 5, application of pulse signal 502 may not affect a bulk switch behavior in CEM layers 522 uniformly between TE 520 and BE 528. For example, a resulting current density in layers of CEM 522 from application of pulse signal 502 may be higher closer to a boundary with TE 520 than closer to a boundary with BE 528. As such, bulk switching behavior in CEM layers 522 may be more pronounced closer to such a boundary with TE 520 than BE 528. In some embodiments, for example, bulk switching behavior in CEM layers 522 closer to a boundary with BE 528 may be negligible. While bulk switching behavior in layers of CEM 522 closer to a boundary with BE 528 may be limited, bulk switching behavior occurring closer to a boundary with TE 520 may be sufficient to implement an operational switching device.

As pointed out above in particular embodiments described above, electrode material provided in TE 520 at a boundary with CEM layers 522 (e.g., electrode material to form electrode layer 421) may comprise a noble metal to provide a sufficiently high work function to facilitate bulk switching in CEM layers 522 closer to a boundary with TE 520 (e.g., enabling implementation of an operational switching device). As such, bulk switching behavior is to occur in CEM layers 522 close to a boundary with TE 520 responsive to electrons passing through boundary between TE 520 and CEM layers 522. In this context, “work function” of an element and/or material means work and/or energy to enable removal an electron from a solid surface of the element and/or material to a point in a vacuum immediately outside the solid surface. Here “immediately” means that the final electron position is far from the surface on the atomic scale, but still too close to the solid to be influenced by ambient electric fields in the vacuum. For example, a noble metal such as Ir or Au may have a work function of ˜5.0 eV. If bulk switching in device 500 is to be limited to application of pulse signal 502 at TE 520 and not from application of a pulse signal at BE 528, a work function of electrode material in BE 528 at a boundary with CEM layers 522 (e.g., in electrode layer 423) need not have as high a work function as electrode material provided in TE 520 at a boundary with CEM layers 522. As such, electrode material in BE 528 at a boundary with CEM layers 522 need not be formed from a noble metal if switching is not to occur from application of a pulse signal at BE 528. As pointed out above, electrode material in BE 528 at a boundary with CEM layers 522 may instead comprise a metal nitride that is sufficiently rich in nitrogen to provide an inert layer to inhibit and/or prevent oxygen from escaping a metal oxide forming CEM layers 522.

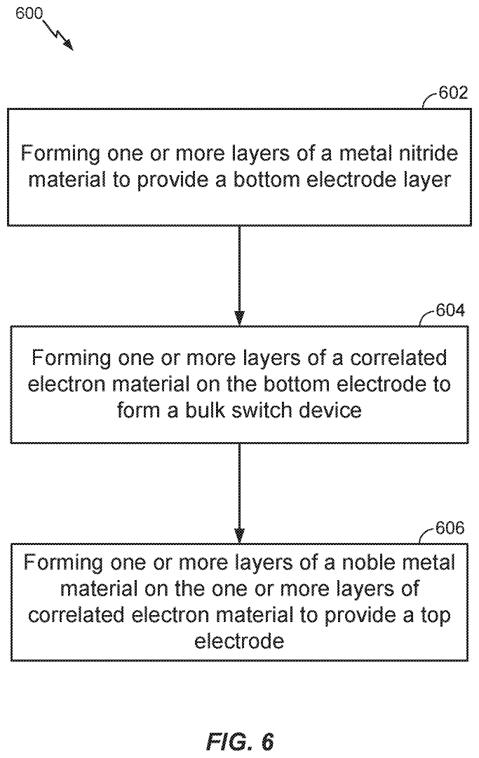

FIG. 6 is a flow diagram of a process to form a switch device according to an embodiment. Block 602 may comprise, for example, formation of at least a portion of at bottom plate layer such as bottom plate layer 528. For example, block 602 may comprise depositing of a metal nitride material (e.g., material for electrode layer 423) being sufficiently rich in nitrogen (e.g., having an atomic concentration of nitrogen of at least 50%) to provide barrier to prevent escape of oxygen from a metal oxide material. As pointed out above, such a metal nitride material may comprise or more of TiN, TaN, MgN, BN or AlN. In one particular implementation, block 602 may comprise depositing a metal nitride material over a substrate of conductive material such as TaN, for example. In an implementation, such metal nitride deposited over a substrate of conductive material such as TaN at block 602 may provide an electrode material between one or more layers of a metal oxide and such a conductive material comprising TaN capable of preventing escape of oxygen from the metal oxide. In an embodiment, block 602 may follow a process to form a bottom plate layer such as bottom plate layer 428, for example.

Block 604 may comprise depositing a material to form one or more layers of a CEM such as layers of CEM 522. For example, block 602 may comprise depositing one or more layers of NiO and/or other metal oxides such as, for example, HfOx, YOx, TiOx and/or TaOx, just to name a few. To bring about switching behavior, such deposited layers of metal oxide may also be doped with a carbon-containing dopant such as, for example, CO, and/or a nitrogen-containing dopant such as, for example, NO, to a particular atomic concentration. Block 604 may also comprise annealing deposited material activate applied dopants to impart backdonation properties.

Block 606 may comprise depositing one or more layers of a noble metal such as, for example, silver, gold, platinum, rhodium, iridium, palladium, ruthenium, and/or rhenium, over layers of material formed at block 604. Layers formed at block 606 may provide, for example, an electrode material (e.g., as electrode layer 421) between layers of material formed at 604 and a top plate layer (e.g., top plate layer 420) comprising a conductive metal such as TaN as discussed above. As pointed out above, such an electrode material comprising a noble metal may provide an oxygen barrier to prevent escape of oxygen in layers of CEM formed at block 604 while also providing a sufficiently high work function enabling bulk switching capabilities responsive to a pulse signal applied to a top electrode.

As pointed out above, layers may be formed at blocks 602, 604 and 606 using any one of several suitable deposition process techniques such as, for example, atomic layer deposition, chemical vapor deposition, plasma chemical vapor deposition, sputter deposition, physical vapor deposition, hot wire chemical vapor deposition, laser enhanced chemical vapor deposition, laser enhanced atomic layer deposition, rapid thermal chemical vapor deposition, spin on deposition, gas cluster ion beam deposition, and/or the like, utilized in fabrication of CEM devices from metal oxide materials. It should be noted, however, layers may be formed at blocks 602, 604 and 606 may be formed utilizing other, different processes, and that claimed subject matter is not intended to be limited in this respect.

Following block 606, a resulting device may be further processed by etching to form a switch device. Since electrode material deposited at block 602 (e.g., to form electrode layer 423) may comprise a nitrogen-rich metal nitride, formation of a resputterred metal as a residue to a sidewall (e.g., sidewall residue 440) of a CEM device may be reduced, removed and/or mitigated using techniques discussed above. Such as, for example, application of an RIE process to remove metal nitride electrode material, an oxidation process to make metal sidewall material more insulative and/or chemical process to remove metal sidewall residue as discussed above.

In the preceding description, in a particular context of usage, such as a situation in which tangible components (and/or similarly, tangible materials) are being discussed, a distinction exists between being “on” and being “over.” As an example, deposition of a substance “on” a substrate refers to a deposition involving direct physical and tangible contact without an intermediary, such as an intermediary substance (e.g., an intermediary substance formed during an intervening process operation), between the substance deposited and the substrate in this latter example; nonetheless, deposition “over” a substrate, while understood to potentially include deposition “on” a substrate (since being “on” may also accurately be described as being “over”), is understood to include a situation in which one or more intermediaries, such as one or more intermediary substances, are present between the substance deposited and the substrate so that the substance deposited is not necessarily in direct physical and tangible contact with the substrate.

A similar distinction is made in an appropriate particular context of usage, such as in which tangible materials and/or tangible components are discussed, between being “beneath” and being “under.” While “beneath,” in such a particular context of usage, is intended to necessarily imply physical and tangible contact (similar to “on,” as just described), “under” potentially includes a situation in which there is direct physical and tangible contact but does not necessarily imply direct physical and tangible contact, such as if one or more intermediaries, such as one or more intermediary substances, are present. Thus, “on” is understood to mean “immediately over” and “beneath” is understood to mean “immediately under.”

It is likewise appreciated that terms such as “over” and “under” are understood in a similar manner as the terms “up,” “down,” “top,” “bottom,” and so on, previously mentioned. These terms may be used to facilitate discussion but are not intended to necessarily restrict scope of claimed subject matter. For example, the term “over,” as an example, is not meant to suggest that claim scope is limited to only situations in which an embodiment is right side up, such as in comparison with the embodiment being upside down, for example. An example includes a flip chip, as one illustration, in which, for example, orientation at various times (e.g., during fabrication) may not necessarily correspond to orientation of a final product. Thus, if an object, as an example, is within applicable claim scope in a particular orientation, such as upside down, as one example, likewise, it is intended that the latter also be interpreted to be included within applicable claim scope in another orientation, such as right side up, again, as an example, and vice-versa, even if applicable literal claim language has the potential to be interpreted otherwise. Of course, again, as always has been the case in the specification of a patent application, particular context of description and/or usage provides helpful guidance regarding reasonable inferences to be drawn.

Unless otherwise indicated, in the context of the present disclosure, the term “or” if used to associate a list, such as A, B, or C, is intended to mean A, B, and C, here used in the inclusive sense, as well as A, B, or C, here used in the exclusive sense. With this understanding, “and” is used in the inclusive sense and intended to mean A, B, and C; whereas “and/or” can be used in an abundance of caution to make clear that all of the foregoing meanings are intended, although such usage is not required. In addition, the term “one or more” and/or similar terms is used to describe any feature, structure, characteristic, and/or the like in the singular, “and/or” is also used to describe a plurality and/or some other combination of features, structures, characteristics, and/or the like. Furthermore, the terms “first,” “second,” “third,” and the like are used to distinguish different aspects, such as different components, as one example, rather than supplying a numerical limit or suggesting a particular order, unless expressly indicated otherwise. Likewise, the term “based on” and/or similar terms are understood as not necessarily intending to convey an exhaustive list of factors, but to allow for existence of additional factors not necessarily expressly described.

Furthermore, it is intended, for a situation that relates to implementation of claimed subject matter and is subject to testing, measurement, and/or specification regarding degree, to be understood in the following manner. As an example, in a given situation, assume a value of a physical property is to be measured. If alternatively reasonable approaches to testing, measurement, and/or specification regarding degree, at least with respect to the property, continuing with the example, is reasonably likely to occur to one of ordinary skill, at least for implementation purposes, claimed subject matter is intended to cover those alternatively reasonable approaches unless otherwise expressly indicated. As an example, if a plot of measurements over a region is produced and implementation of claimed subject matter refers to employing a measurement of slope over the region, but a variety of reasonable and alternative techniques to estimate the slope over that region exist, claimed subject matter is intended to cover those reasonable alternative techniques, even if those reasonable alternative techniques do not provide identical values, identical measurements or identical results, unless otherwise expressly indicated.

It is further noted that the terms “type” and/or “like,” if used, such as with a feature, structure, characteristic, and/or the like, using “optical” or “electrical” as simple examples, means at least partially of and/or relating to the feature, structure, characteristic, and/or the like in such a way that presence of minor variations, even variations that might otherwise not be considered fully consistent with the feature, structure, characteristic, and/or the like, do not in general prevent the feature, structure, characteristic, and/or the like from being of a “type” and/or being “like,” (such as being an “optical-type” or being “optical-like,” for example) if the minor variations are sufficiently minor so that the feature, structure, characteristic, and/or the like would still be considered to be predominantly present with such variations also present. Thus, continuing with this example, the terms optical-type and/or optical-like properties are necessarily intended to include optical properties. Likewise, the terms electrical-type and/or electrical-like properties, as another example, are necessarily intended to include electrical properties. It should be noted that the specification of the present disclosure merely provides one or more illustrative examples and claimed subject matter is intended to not be limited to one or more illustrative examples; however, again, as has always been the case with respect to the specification of a patent application, particular context of description and/or usage provides helpful guidance regarding reasonable inferences to be drawn.

In the preceding description, various aspects of claimed subject matter have been described. For purposes of explanation, specifics, such as amounts, systems, and/or configurations, as examples, were set forth. In other instances, well-known features were omitted and/or simplified so as not to obscure claimed subject matter. While certain features have been illustrated and/or described herein, many modifications, substitutions, changes, and/or equivalents will occur to those skilled in the art. It is, therefore, to be understood that the appended claims are intended to cover all modifications and/or changes as fall within claimed subject matter.

What is claimed is:

1. A device comprising:
one or more bottom electrode layers comprising substantially a metal nitride material;
one or more layers of a correlated electron material formed on the one or more bottom electrode layers to from a bulk switch device; and
one or more top electrode layers comprising a noble metal material.

2. The device of claim 1, wherein the metal nitride material has an atomic concentration of nitrogen at least 50%.

3. The device of claim 1, wherein the metal nitride material comprises substantially no metal-to-metal bonds.

4. The device of claim 1, wherein the correlated electron material comprises a metal oxide, and wherein the bottom electrode layer substantially inhibits and/or prevents escape of oxygen from the one or more layers of correlated electron material.

5. The device of claim 1, wherein the device is adapted to receive a pulse signal at the one or more top electrode layers to transition the bulk switch device between a high impedance and/or insulative state and a low impedance and/or conductive state, the pulse signal to comprise a positive polarity relative to the one or more bottom electrode layers.

6. The device of claim 5, wherein application of the pulse signal at the one or more top electrode layers to affect a current density in one or more layers of correlated electron material more significantly closer to a boundary with the one or more top electrode layers than to a boundary with the one or more bottom electrode layers.

7. The device of claim 5, wherein bulk switching behavior in the one or more layers of correlated electron material responsive to application of the pulse signal at the one or more top electrode layers to be more pronounced in a region of the one or more layers of the correlated electron material closer to the one or more top electrode layers than to the one or more bottom electrode layers.

8. The device of claim 1, wherein the one or more top electrode layers comprise silver, gold, platinum, rhodium, iridium, palladium, ruthenium or rhenium, or a combination thereof.

9. The device of claim 1, wherein the one or more bottom electrode layers comprise TiN, TaN, MgN, BN or AlN, or a combination thereof.

10. The device of claim 1, wherein a sidewall portion of the bulk switch device comprises a metal oxide species of a metal forming the one or more bottom electrode layers.

11. The device of claim 1, wherein the noble metal material comprises a substantially higher work function than the metal nitride material.

12. A method comprising:
forming one or more layers of a metal nitride material to provide a bottom electrode layer;
forming one or more layers of a correlated electron material (CEM) on the bottom electrode layer to form a bulk switch device; and
forming one or more layers of a noble metal material on the one or more layers of the one or more layers of correlated electron material to provide a top electrode layer.

13. The method of claim 12, and further comprising etching top electrode layer, the one or more layers of the CEM and the bottom electrode layer to form a correlated electron switch device.

14. The method of claim 13, and further comprising applying an oxidation treatment to oxidize metal residue forming on a sidewall of the one or more layers of the CEM from etching metal nitride in the bottom electrode layer.

15. The method of claim 13, and further comprising applying a chemical a wet clean process and/or a reactive ion etch process to at least partially remove residue forming on a sidewall of the one or more layers of the CEM from etching metal nitride in the bottom electrode layer.

16. The method of claim 12, and further comprising:
applying a first etching process to remove portions of the one or more layers of the noble metal material forming the top electrode layer and the one or more layers of CEM to form the bulk switch;
terminating the first etching process prior to etch of the bottom electrode layer; and
applying a second etching process to remove portions of the one or more layers of metal nitride material forming the bottom electrode layer.

17. The method of claim 16, wherein the first etching process comprises an ion beam etch (IBE) process and the second etching process comprises a reactive ion etch (RIE) process.

18. The method of claim 12, wherein the noble metal material comprises silver, gold, platinum, rhodium, iridium, palladium, ruthenium or rhenium, or a combination thereof.

19. The method of claim 12, wherein the metal nitride material comprises TiN, TaN, MgN, BN or AlN, or a combination thereof.

20. The method of claim 12, wherein the forming the one or more layers of the CEM on the bottom electrode further comprises:
depositing one or more layers of a metal oxide on the bottom electrode;
applying a dopant to the one or more layers of the metal oxide; and
annealing the one or more layers of the one or more layers of the metal oxide to activate the dopant to bring about a backdonation property.
